(19) United States
(12) Patent Application Publication
(10) Pub. No.: US 2026/0302632 A1
(43) Pub. Date: Oct. 1, 2026

(54) ANTENNA DEVICE AND COMMUNICATION TERMINAL DEVICE

(71) Applicant: Murata Manufacturing Co., Ltd., Nagaokakyo-shi (JP)

(72) Inventor: Toumu TANABE, Nagaokakyo-shi (JP)

(73) Assignee: Murata Manufacturing Co., Ltd., Nagaokakyo-shi (JP)

(21) Appl. No.: 19/693,605

(22) Filed: Jun. 1, 2026

Related U.S. Application Data
(63) Continuation of application No. PCT/JP2024/035765, filed on Oct. 7, 2024.

(30) Foreign Application Priority Data
Dec. 20, 2023 (JP) 2023-214523

(51) Int. Cl. H01Q 9/30; H01Q 5/20; H01Q 7/00

(52) U.S. Cl. CPC H01Q 9/30; H01Q 5/20; H01Q 7/00

(57) ABSTRACT

Provided are an antenna device and a communication terminal device that allow the frequency band to be broadened or multiple frequency bands to be supported without degradation of antenna characteristics. An antenna device of the present disclosure includes a first radiating element to which a feeder circuit is connected, a second radiating element, a first coil connected to the first radiating element, a second coil connected between the second radiating element and a ground electrode and electromagnetically coupled with the first coil, and a capacitor connected in parallel with the second coil and constituting a parallel resonant circuit together with the second coil. The resonant frequency of the parallel resonant circuit is a frequency within the band of a fundamental resonance or a harmonic resonance of the first radiating element.

### CROSS-REFERENCE TO RELATED APPLICATIONS

This application is a continuation of International Application No. PCT/JP2024/035765, filed on Oct. 7, 2024, which claims priority to Japanese Patent Application No. 2023-214523, filed on Dec. 20, 2023, the entire contents of each of which are incorporated herein by reference in their entireties.

### TECHNICAL FIELD

The present disclosure relates to technologies of antenna devices and communication terminal devices.

### BACKGROUND ART

In recent years, communication terminal devices have employed antenna devices that include two radiating elements that are directly or indirectly coupled in order to broaden the frequency bandwidth or to allow support of multiple frequency bands. Specifically, an antenna device in which two radiating elements are electromagnetically coupled using a transformer element is described in Japanese Patent No. 6760545 (Patent Document 1).

### CITATION LIST

### Patent Document

Patent Document 1: Japanese Patent No. 6760545

### SUMMARY

An antenna device according to the present disclosure includes a first radiating element to which a feeder circuit is connected, a second radiating element, a first coil connected to the first radiating element, a second coil connected between the second radiating element and a ground electrode and electromagnetically coupled to the first coil, and a capacitance circuit connected in parallel with the second coil and constituting a parallel resonant circuit together with the second coil. A resonant frequency of the parallel resonant circuit is a frequency within a band of a fundamental resonance or a harmonic resonance of the first radiating element.

A communication terminal device according to the present disclosure includes the above-described antenna device and the feeder circuit.

### BRIEF DESCRIPTION OF DRAWINGS

FIG. 1 is a circuit diagram of an antenna device of Embodiment 1.

FIG. 2 is a schematic diagram illustrating a communication terminal device of Embodiment 1.

FIG. 3 is a diagram illustrating the frequency characteristics of the radiation efficiency of the antenna device of Embodiment 1.

FIG. 4 is a diagram for explaining the relationship between the polarity of a transformer element and the resonant frequency of an antenna device.

FIG. 5 is a diagram for explaining the relationship between the polarity of a transformer element and the resonant frequency of an antenna device.

FIG. 6 is a schematic diagram of an antenna device of Modification 1.

FIG. 7 is a schematic diagram of an antenna device of Modification 2.

FIG. 8 is a schematic diagram of an antenna device of Modification 3.

FIG. 9 is a schematic diagram of an antenna device of Modification 4.

FIG. 10 is a schematic diagram of an antenna device of Modification 5.

FIG. 11 is a circuit diagram of an antenna device of Embodiment 2.

FIG. 12 is a circuit diagram of an antenna device of Embodiment 3.

FIG. 13 is a circuit diagram of another antenna device of Embodiment 3.

### DESCRIPTION OF EMBODIMENTS

In the antenna device described in Patent Document 1, a first radiating element connected to a feeder circuit and a second radiating element not connected to a feeder circuit are electromagnetically coupled using a transformer element. However, the inventor has recognized that, in the antenna device described in Patent Document 1, a current from the feeder circuit may sometimes not only flow to the first radiating element but also to the second radiating element via a ground electrode (ground board). When a current from the feeder circuit flows to the second radiating element, there is a risk that the antenna characteristics (for example, radiation efficiency) will be degraded.

The present disclosure was made in order to solve such a problem, as well as others, and is directed to providing an antenna device and a communication terminal device that allow the frequency band to be broadened or multiple frequency bands to be supported without degradation of the antenna characteristics.

The antenna device according to the present disclosure includes the capacitance circuit that constitutes a parallel resonant circuit together with the second coil. The resonant frequency of the parallel resonant circuit falls within the frequency band of a fundamental resonance or a harmonic resonance of the first radiating element. As used herein, “within a band of a resonance” means within the operating frequency band associated with that resonance, i.e., within the −10 dB return loss bandwidth or other bandwidth criterion appropriate to the application. This allows the frequency band to be widened or for multiple frequency bands to be supported without degradation of the antenna characteristics.

Embodiments of the present disclosure will be described in detail below with reference to the drawings. In the drawings, the same or corresponding parts are denoted by the same reference symbols, and description thereof is not repeated.

### Embodiment 1

FIG. 1 is a circuit diagram of an antenna device 100 of Embodiment 1. The antenna device 100 includes a first antenna and a second antenna. The first antenna includes a first radiating element 11 to which a feeder circuit 30 is connected, and a first coil L1 connected in series with the feeder circuit 30 between the first radiating element 11 and a ground electrode. In other embodiments, the first coil L1 may alternatively be connected in parallel with the feeder circuit 30, as described below.

The second antenna includes a second radiating element 12, a second coil L2 connected in series with the second radiating element 12, and a capacitor C2 (capacitance circuit) connected in parallel with the second coil L2. The second coil L2 and the capacitor C2 constitute a parallel resonant circuit 25. The first coil L1 and the second coil L2 are electromagnetically coupled with each other. In the antenna device 100, the first antenna functions as a fed antenna fed by the feeder circuit 30, whereas the second antenna functions as a parasitic antenna (i.e., an antenna element that is not directly fed by the feeder circuit but is electromagnetically coupled to the fed antenna) not fed by the feeder circuit 30.

The first coil L1 and the second coil L2 are mounted in the antenna device 100 as, for example, a transformer element 20. The transformer element 20 is, for example, a rectangular-parallelepiped-shaped chip component. The transformer element 20 is constructed by forming the conductor patterns of the first coil L1 and the second coil L2 on insulating substrates (for example, liquid crystal polymer, low-temperature co-fired ceramics, etc.) and then stacking the insulating substrates. The transformer element 20 may be configured as a separate component from the capacitor C2, which forms the parallel resonant circuit 25 together with the second coil L2, or may be configured as a single component including the capacitor C2.

Antenna devices implemented in mobile devices such as smartphones employ a combination of a fed antenna and a parasitic antenna using a transformer element in order to broaden the frequency bandwidth or to allow support of multiple frequency bands. In other words, the antenna device forms a transformer-coupled multiband communication antenna. However, in antenna devices in which the first radiating element and the second radiating element are coupled by a transformer element, a current from the feeder circuit may flow directly to the second radiating element via a ground electrode. When a current from the feeder circuit flows directly to the second radiating element, there is a risk that the current flowing to the first radiating element will decrease, resulting in degradation of antenna characteristics (e.g., radiation efficiency).

Therefore, in the antenna device 100 according to this embodiment, the second coil L2 is connected in parallel with the capacitor C2, and the second coil L2 and capacitor C2 constitute the parallel resonant circuit 25. The parallel resonant circuit 25 is configured such that the resonant frequency thereof lies within the band of the fundamental resonance or a harmonic resonance of the first radiating element 11. By setting the parallel resonant frequency of the second coil L2 and the capacitor C2 to a frequency within the band of the fundamental resonance or a harmonic resonance of the first radiating element 11, the current at that frequency is blocked by the parallel resonant circuit 25, thereby suppressing a current flowing from the feeder circuit 30 to the second radiating element 12, and ensuring that the current flows efficiently from the feeder circuit 30 to the first radiating element 11. In other words, the impedance of the parallel resonant circuit 25 is maximized at the resonant frequency of the parallel resonant circuit 25, thereby blocking current flow through that path.

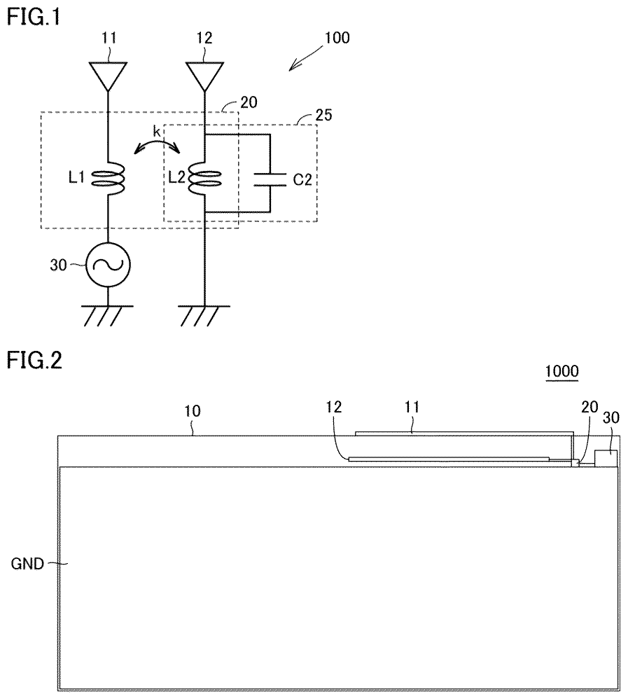

Specifically, a case will be described in which the antenna device 100 is implemented in a communication terminal device. FIG. 2 is a schematic diagram illustrating a communication terminal device 1000 of Embodiment 1. The communication terminal device 1000 illustrated in FIG. 2 is capable of communicating in, for example, a band containing approximately 1.0 GHz and a band containing approximately 2.2 GHZ. The communication terminal device 1000 is, for example, a smartphone, and a substrate 10 provided with the antenna device 100 is mounted on a part of the casing.

The first radiating element 11, the second radiating element 12, the transformer element 20, and the feeder circuit 30, which constitute the antenna device 100, are mounted on the substrate 10. The first radiating element 11 and the second radiating element 12 are electromagnetically coupled via the transformer element 20, as illustrated in FIG. 1. One end of the first radiating element 11 is connected to a ground electrode GND via the transformer element 20 and the feeder circuit 30. One end of the second radiating element 12 is connected to the ground electrode GND via the transformer element 20.

As illustrated in FIG. 1, the transformer element 20 includes the parallel resonant circuit 25, and therefore a current flowing from the feeder circuit 30 to the second radiating element 12 is suppressed, allowing the current from the feed circuit 30 to flow efficiently to the first radiating element 11. Therefore, the antenna device 100 can broaden the frequency bandwidth or allow support of multiple frequency bands without degradation of the antenna characteristics.

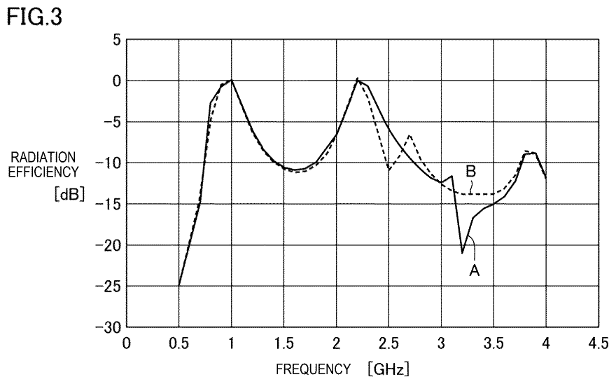

FIG. 3 is a diagram illustrating the frequency characteristics of the radiation efficiency of the antenna device 100 of Embodiment 1. In FIG. 3, the horizontal axis represents frequency, and the vertical axis represents radiation efficiency. The frequency characteristics of the radiation efficiency illustrated in FIG. 3 are the results of a simulation performed for the configuration of the antenna device 100 illustrated in FIG. 2. Specifically, a simulation of the antenna device 100 was performed with the first coil L1=1 nH, the second coil L2=5 nH, a coupling coefficient k=−0.5, and the capacitor C2=1.5 pF. In addition, for the first antenna, a simulation was performed assuming that an inductance (17 nH) and a capacitance (2 pF) were connected in series with the first radiating element 11, separate from the first coil L1. The values above are used for illustrative purposes only and the component values may be adjusted to target different frequency bands or antenna configuration.

In FIG. 3, a solid line graph A represents the frequency characteristics of the radiation efficiency of the antenna device 100 and a dashed line graph B represents the frequency characteristics of the radiation efficiency of an antenna device without the capacitor C2. Graph B shows that the radiation efficiency in a frequency band containing approximately 2.4 GHz is reduced due to a current flowing from the feeder circuit 30 to the second radiating element 12. On the other hand, in graph A, since the current flowing from the feeder circuit 30 to the second radiating element 12 is suppressed by the parallel resonant circuit 25, the radiation efficiency in the band containing approximately 2.4 GHz is not reduced.

This is because the frequency of the fundamental resonance of the first radiating element 11, illustrated in FIG. 3, is approximately 0.8 GHZ, and the resonance frequency of the parallel resonant circuit 25 of the antenna device 100 has been adjusted by selecting an appropriate capacitance value for the capacitor C2 to approximately 2.4 GHz, which is the frequency of the third harmonic resonance of the first radiating element 11. As a result of adjusting the resonant frequency of the parallel resonant circuit 25, which consists of the second coil L2 and the capacitor C2, to lie within the frequency band of the third harmonic resonance of the first radiating element 11, the antenna device 100 can maintain high radiation efficiency without any degradation in the frequency band containing approximately 2.4 GHz, as in FIG. 3.

The frequency of the fundamental resonance of the second radiating element 12 illustrated in FIG. 3 is adjusted to a frequency that lies within the frequency band of the fundamental resonance of the first radiating element 11. Consequently, in graph A in FIG. 3, the radiation efficiency is high in the frequency band containing approximately 0.8 GHZ. Note that adjusting the frequency of the fundamental resonance of the second radiating element 12 to a frequency that lies within the frequency band of the fundamental resonance of the first radiating element 11 is just one example, and the frequency may be adjusted to a different frequency. Furthermore, the resonant frequency of the parallel resonant circuit 25 is not limited to a frequency within the frequency band of the third harmonic resonance of the first radiating element 11, but may also be a frequency within the frequency band of other harmonic resonances or within the frequency band of the fundamental resonance.

In the antenna device 100, the second antenna is provided to compensate for the insufficient bandwidth of the first antenna, and the two antennas are coupled with the transformer element 20 to broaden the bandwidth. When putting the antenna device 100 into actual use, as illustrated in FIG. 2, the area in which the radiating elements are formed is limited, and the first radiating element 11 and the second radiating element 12 are in close proximity to each other. In this case, it is necessary to design the antenna device 100 so that the antenna characteristics are not degraded by interference between the first antenna and the second antenna.

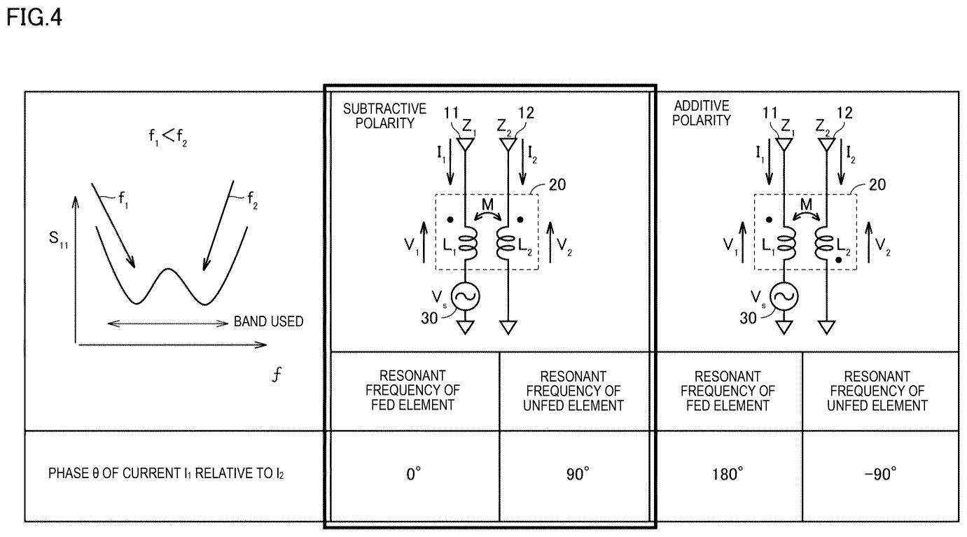

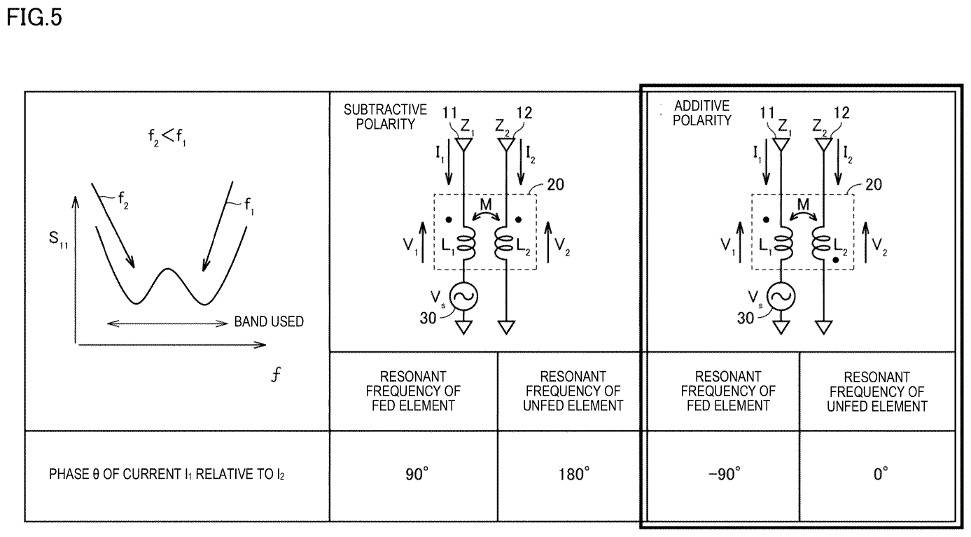

Specifically, in order to suppress interference between the first antenna and the second antenna, it is necessary to determine the polarity of the transformer element 20 so that the phase of the current flowing through the first coil L1 and the phase of the current flowing through the second coil L2 are opposite. FIGS. 4 and 5 are diagrams for explaining the relationship between the polarity of a transformer element and the resonant frequency of an antenna device.

The antenna devices illustrated in FIGS. 4 and 5 do not include the capacitor C2 for simplicity of explanation, and the first radiating element 11 and the second radiating element 12 are coupled by the transformer element 20. The impedance of the first radiating element 11 is Z₁, and the current flowing through the first radiating element 11 is I₁. The voltage across the first coil L1 is V₁, and the voltage across the feeder circuit 30 is Vs. Furthermore, the impedance of the second radiating element 12 is Z₂, and the current flowing through the second radiating element 12 is I₂. The voltage across the second coil L2 is V₂. Furthermore, the mutual inductance between the first coil L1 and the second coil L2 is M, with the mutual inductance being +M when the polarity of the transformer element is a subtractive polarity and −M when the polarity of the transformer element is an additive polarity. Note that in the expressions herein, the sign of the mutual inductance M is defined such that M is positive (+M) when the transformer element has a subtractive polarity as defined above, and negative (−M) when the transformer element has an additive polarity as defined above.

In the antenna devices illustrated in FIGS. 4 and 5, the polarity of the transformer element is a subtractive polarity when the conductors of the first coil L1 and the second coil L2 are wound such that the direction of the magnetic flux generated by the first coil L1 when current flows from the first radiating element 11 toward the feeder circuit 30 is opposite to the direction of the magnetic flux generated by the second coil L2 when current flows from the second radiating element 12 toward the ground electrode. Conversely, the polarity of the transformer element is an additive polarity when the conductors of the first coil L1 and the second coil L2 are wound such that the direction of the magnetic flux generated by the first coil L1 when current flows from the first radiating element 11 toward the feeder circuit 30 is the same as the direction of the magnetic flux generated by the second coil L2 when current flows from the second radiating element 12 toward the ground electrode.

As defined above, Equation (1) shows that the relationship between the current I₁ of the first radiating element 11 and the current I₂ of the second radiating element 12 is determined by the polarity of the transformer element and the impedance of the second coil L2.

$$\begin{matrix}[ Math 1 ] & \\ \frac{{I}_{1}}{{I}_{2}} = \pm j \frac{{Z}_{2} + j ω {L}_{2}}{ω M} & ( Equation 1 )\end{matrix}$$

The impedance Z₂ of the second radiating element 12, which is a parasitic antenna, at the resonant frequency of the first radiating element 11, which is a fed antenna, is capacitive when a resonant frequency f₂ of the second radiating element 12 is greater than a resonant frequency f₁ of the first radiating element 11 (f₁<f₂). Therefore, the impedance Z₂ can be expressed as in Equation (2). Here, C in Equation (2) is the capacitive component in an equivalent circuit of the second antenna, which is a parasitic antenna. The resistance component of this equivalent circuit is ignored.

$$\begin{matrix}[ Math 2 ] & \\ {Z}_{2} + j ω {L}_{2} ≅ - j \frac{1}{ω C} & ( Equation 2 )\end{matrix}$$

By applying Equation (2) to Equation (1), the relationship between the current I₂ of the second radiating element 12 and the current I₁ of the first radiating element 11 can be expressed as Equation (3).

$$\begin{matrix}[ Math 3 ] & \\ \frac{{I}_{1}}{{I}_{2}} = \pm \frac{1}{ω MC} & ( Equation 3 )\end{matrix}$$

From Equation (3), a phase θ of the current I₁ of the first radiating element 11 with respect to the current I₂ of the second radiating element 12 is 0° in the case of a subtractive polarity and 180° in the case of an additive polarity, as shown in Equation (4). Therefore, when the resonant frequency f₂ of the second radiating element 12 is greater than the resonant frequency f₁ of the first radiating element 11 (f₁<f₂), the antenna device 100 may use the transformer element 20 with an in-phase subtractive-polarity configuration in order to suppress interference between the first antenna and the second antenna. FIG. 4 illustrates a summary of the polarities of the transformer element 20 when the resonant frequency f₂ of the second radiating element 12 is greater than the resonant frequency f₁ of the first radiating element 11 (f₁<f₂).

$$\begin{matrix}[ Math 4 ] & \\ θ = {tan}^{- 1} \frac{0}{\frac{1}{{ω}^{2} MC}} = 0 ° , θ = {tan}^{- 1} - \frac{0}{\frac{1}{{ω}^{2} MC}} = 180 ° & ( Equation 4 )\end{matrix}$$

On the other hand, the impedance Z₂ of the second radiating element 12 at the resonant frequency of the first radiating element 11 is inductive when the resonant frequency f₂ of the second radiating element 12 is smaller than the resonant frequency f₁ of the first radiating element 11 (f₁>f₂). Therefore, the impedance Z₂ can be expressed as in Equation (5). Here, L in Equation (5) is the inductance component in an equivalent circuit of the second antenna, which is a parasitic antenna. The resistance component of this equivalent circuit is ignored.

$$\begin{matrix}[ Math 5 ] & \\ {Z}_{2} + j ω {L}_{2} ≅ j ω L & ( Equation 5 )\end{matrix}$$

By applying Equation (5) to Equation (1), the relationship between the current I₁ of the first radiating element 11 and the current I₂ of the second radiating element 12 can be expressed as Equation (6).

$$\begin{matrix}[ Math 6 ] & \\ \frac{{I}_{1}}{{I}_{2}} = ∓ \frac{L}{M} & ( Equation 6 )\end{matrix}$$

From Equation (6), the phase θ of the current I₁ of the first radiating element 11 with respect to the current I₂ of the second radiating element 12 is 180° in the case of a subtractive polarity and 0° in the case of an additive polarity, as shown in Equation (7). Therefore, when the resonant frequency f₂ of the second radiating element 12 is smaller than the resonant frequency f₁ of the first radiating element 11 (f₁>f₂), the antenna device 100 may use the transformer element 20 with an in-phase additive-polarity configuration in order to suppress interference between the first antenna and the second antenna. FIG. 5 illustrates a summary of the polarities of the transformer element 20 when the resonant frequency f₂ of the second radiating element 12 is smaller than the resonant frequency f₁ of the first radiating element 11 (f₁>f₂).

$$\begin{matrix}[ Math 7 ] & \\ θ = {tan}^{- 1} - \frac{0}{\frac{L}{M}} = 180 ° , θ = {tan}^{- 1} \frac{0}{\frac{L}{M}} = 0 ° & ( Equation 7 )\end{matrix}$$

In the above description, the relationship between the current I₁ of the first radiating element 11 and the current I₂ of the second radiating element 12 was determined while assuming that the first antenna and the second antenna are completely independent. However, if the first antenna and the second antenna are not completely independent and there is coupling therebetween, the relationship can be determined by superimposing the phase relationship derived above with the phase relationship resulting from the coupling between the antennas.

### MODIFICATIONS

In the above description, the types of the first and second antennas of the antenna device 100 are not particularly limited. Hereafter, modifications in which the types of the first antenna and the second antenna in the antenna device are limited will be described. Note that the limitations on the types of the first antenna and the second antenna described below can also be applied to other embodiments.

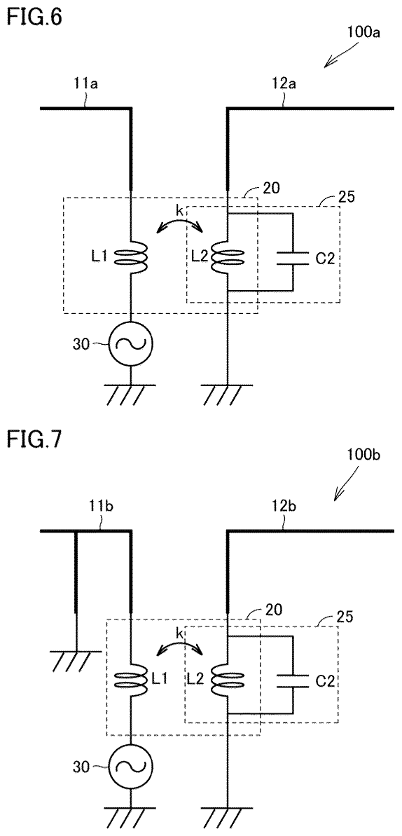

FIG. 6 is a schematic diagram of an antenna device 100a of Modification 1. In the antenna device 100a illustrated in FIG. 6, components identical to those in the antenna device 100 illustrated in FIG. 1 are denoted by the same reference symbols, and detailed descriptions thereof are not repeated. In the antenna device 100a, a first radiating element 11a constitutes a monopole antenna, and a second radiating element 12a also constitutes a monopole antenna. The antenna device 100a is a basic antenna configuration, and the frequency bandwidth can be further widened by allowing two monopole antennas having a wide frequency bandwidth to couple with each other. The resonant frequency of the parallel resonant circuit 25, which consists of the second coil L2 and the capacitor C2, lies within the frequency band of the feeder circuit 30 that supplies a current to the first radiating element 11a (the fundamental resonant frequency of the first radiating element 11a).

FIG. 7 is a schematic diagram of an antenna device 100b of Modification 2. In the antenna device 100b illustrated in FIG. 7, components that are the same as those in the antenna device 100 illustrated in FIG. 1 are denoted by the same reference symbols, and detailed descriptions thereof are not repeated. In the antenna device 100b, a first radiating element 11b constitutes an inverted-F antenna (IFA), and a second radiating element 12b constitutes a monopole antenna. Because the first radiating element 11b is an inverted-F antenna, the design flexibility of the antenna device 100b is improved. In addition, since the first radiating element 11b has a path that is grounded to a ground electrode at an intermediate point between the feeder circuit 30 and an end portion of the first radiating element 11b, external influences such as a human body can be suppressed. The resonant frequency of the parallel resonant circuit 25, which consists of the second coil L2 and the capacitor C2, lies within the frequency band of the feeder circuit 30 that supplies a current to the first radiating element 11b (fundamental resonant frequency of first radiating element 11b).

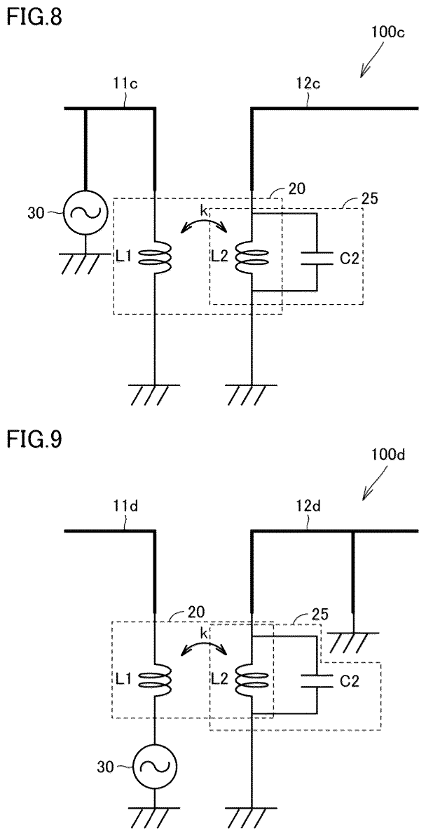

FIG. 8 is a schematic diagram of an antenna device 100c of Modification 3. In the antenna device 100c illustrated in FIG. 8, components that are the same as those in the antenna device 100 illustrated in FIG. 1 are denoted by the same reference symbols, and detailed descriptions thereof are not repeated. In the antenna device 100c, a first radiating element 11c constitutes an inverted-F antenna, and a second radiating element 12c constitutes a monopole antenna. Unlike the first radiating element 11b of the inverted-F antenna illustrated in FIG. 7, the first radiating element 11c connects the first coil L1 to a path that is not connected to the feeder circuit 30. In other words, the first coil L1 is connected in parallel with the feeder circuit 30 between the first radiating element 11c and the ground electrode. Therefore, since the first coil L1 is not present on a path connecting the first radiating element 11c and the feeder circuit 30, power loss due to the first coil L1 can be reduced.

The antenna device 100c has improved design flexibility because the first radiating element 11c is an inverted-F antenna. Furthermore, the first radiating element 11c includes a path that is grounded to a ground electrode separate from the path from the feeder circuit 30 to an end portion of the first radiating element 11c, and therefore external influences such as those from a human body can be suppressed. The resonant frequency of the parallel resonant circuit 25, which consists of the second coil L2 and the capacitor C2, lies within the frequency band of the feeder circuit 30 that supplies a current to the first radiating element 11c (the fundamental resonant frequency of the first radiating element 11c).

FIG. 9 is a schematic diagram of an antenna device 100d of Modification 4. In the antenna device 100d illustrated in FIG. 9, components that are the same as those in the antenna device 100 illustrated in FIG. 1 are denoted by the same reference symbols, and detailed descriptions thereof are not repeated. In the antenna device 100d, a first radiating element 11d constitutes a monopole antenna, and a second radiating element 12d constitutes an inverted-F antenna. Because the second radiating element 12d is an inverted-F antenna, the antenna device 100d has improved design flexibility. In particular, the phase relationship between the current of the first radiating element 11d and the current of the second radiating element 12d can be adjusted by providing an inductance element or a capacitance element on a path that is grounded to a ground electrode at an intermediate point between the feeder circuit 30 and an end portion of the first radiating element 11d.

Furthermore, since the first radiating element 11d has a path that is connected to a ground electrode at an intermediate point between the feeder circuit 30 and an end portion of the first radiating element 11d, external influences such as those from a human body can be suppressed. The resonant frequency of the parallel resonant circuit 25, which consists of the second coil L2 and the capacitor C2, lies within the frequency band of the feeder circuit 30 that supplies a current to the first radiating element 11d (the fundamental resonant frequency of the first radiating element 11d).

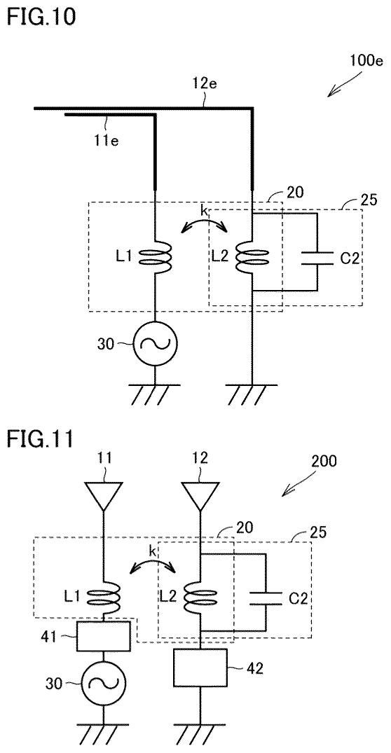

FIG. 10 is a schematic diagram of an antenna device 100e of Modification 5. In the antenna device 100e illustrated in FIG. 10, components that are the same as those in the antenna device 100 illustrated in FIG. 1 are denoted by the same reference symbols, and detailed descriptions thereof are not repeated. In the antenna device 100e, a first radiating element 11e constitutes a monopole antenna, and a second radiating element 12e also constitutes a monopole antenna. In the antenna device 100e, by providing the parallel resonant circuit 25 consisting of the second coil L2 and the capacitor C2, the influence of the second radiating element 12e on the first radiating element 11e can be suppressed, and the second radiating element 12e can be disposed close to the first radiating element 11e as in FIG. 10. The resonant frequency of the parallel resonant circuit 25 consisting of the second coil L2 and the capacitor C2 lies within the frequency band of the feeder circuit 30 that supplies a current to the first radiating element 11e (the fundamental resonant frequency of the first radiating element 11e).

### Embodiment 2

In the above-described embodiment, the first radiating element 11 is connected to the ground electrode via the first coil L1 and the feeder circuit 30, and the second radiating element 12 is connected to the ground electrode via the second coil L2. However, a matching network may be provided for one or both of the first antenna, which includes the first radiating element, and the second antenna, which includes the second radiating element, in order to realize impedance matching therebetween. FIG. 11 is a circuit diagram of an antenna device 200 of Embodiment 2. In the antenna device 200 illustrated in FIG. 11, components that are the same as those in the antenna device 100 illustrated in FIG. 1 are denoted by the same reference symbols, and detailed descriptions thereof are not repeated.

The antenna device 200 includes a first antenna and a second antenna. The first antenna includes a first radiating element 11, to which a feeder circuit 30 is connected, and a first coil L1 and a matching network 41 (first matching network) connected in series between the first radiating element 11 and the feeder circuit 30.

The second antenna includes a second radiating element 12, a second coil L2 and a matching network 42 (second matching network) connected in series with the second radiating element 12, and a capacitor C2 (capacitance circuit) connected in parallel with the second coil L2. The second coil L2 and the capacitor C2 constitute a parallel resonant circuit 25. The first coil L1 and the second coil L2 are electromagnetically coupled with each other.

In the antenna device 200, the first antenna functions as a fed antenna fed by the feeder circuit 30, and the second antenna functions as a parasitic antenna that is not fed by the feeder circuit 30. The impedances of the first antenna and the second antenna are matched using the matching networks 41 and 42. The matching networks 41 and 42 include inductors, capacitors, or circuits containing inductors and capacitors.

The antenna device 200 can realize optimized isolation between the first radiating element 11 and the second radiating element 12 by matching the impedance of the first antenna with the impedance of the second antenna. The configurations described in Embodiment 1 can be adopted as appropriate for the antenna device 200.

### Embodiment 3

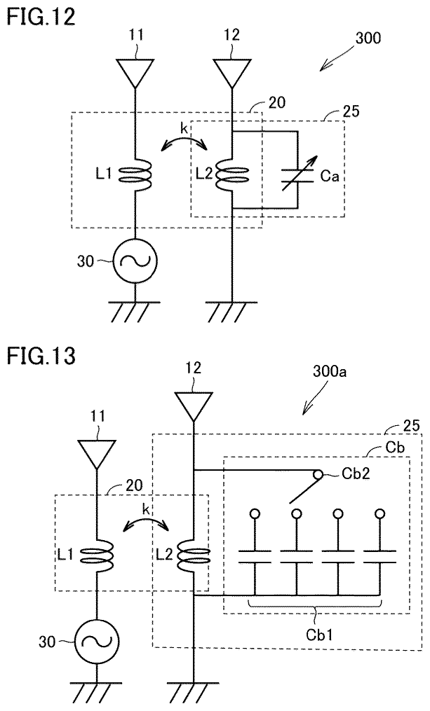

In the previously described embodiments, the capacitance of the capacitor C2 connected in parallel with the second coil L2 was described as having a fixed value. However, a capacitance circuit with a variable capacitance may be used instead of the capacitor C2. FIG. 12 is a circuit diagram of an antenna device 300 of Embodiment 3. In the antenna device 300 illustrated in FIG. 12, components that are the same as those in the antenna device 100 illustrated in FIG. 1 are denoted by the same reference symbols, and detailed descriptions thereof are not repeated.

The antenna device 300 includes a first antenna and a second antenna. The first antenna includes a first radiating element 11 to which a feeder circuit 30 is connected, and a first coil L1 connected in series between the first radiating element 11 and the feeder circuit 30.

The second antenna includes a second radiating element 12, a second coil L2 connected in series with the second radiating element 12, and a variable capacitance element Ca (capacitance circuit) connected in parallel with the second coil L2. The second coil L2 and the variable capacitance element Ca constitute a parallel resonant circuit 25. The first coil L1 and the second coil L2 are electromagnetically coupled with each other.

In the antenna device 300, the first antenna functions as a fed antenna fed by the feeder circuit 30, and the second antenna functions as a parasitic antenna not fed by the feeder circuit 30. Since the capacitance of the variable capacitance element Ca can be varied, the resonant frequency of the parallel resonant circuit 25 can be adjusted. By adjusting the resonant frequency of the parallel resonant circuit 25, the antenna device 300 can block the current flowing from the feeder circuit 30 to the second radiating element 12 over a wider bandwidth, thereby widening the frequency bandwidth.

Furthermore, if a control circuit is provided to adjust the capacitance of the variable capacitance element Ca, the resonant frequency of the parallel resonant circuit 25 can be actively adjusted. For example, the antenna device 300 can adjust the frequency band in which no current flows to the second radiating element 12 by adjusting the capacitance of the variable capacitance element Ca over time using the control circuit.

A capacitance circuit with a variable capacitance is not limited to the variable capacitance element Ca, and may also be a capacitance circuit that allows multiple capacitors with different capacitances to be switched between using a switch element. FIG. 13 is a circuit diagram of another antenna device 300a of Embodiment 3. In the antenna device 300a illustrated in FIG. 13, components that are the same as those in the antenna device 100 illustrated in FIG. 1 are denoted by the same reference symbols, and detailed descriptions thereof are not repeated.

The antenna device 300a includes a first antenna and a second antenna. The first antenna includes a first radiating element 11 to which a feeder circuit 30 is connected, and a first coil L1 connected in series between the first radiating element 11 and the feeder circuit 30.

The second antenna includes a second radiating element 12, a second coil L2 connected in series with the second radiating element 12, and a capacitance circuit Cb connected in parallel with the second coil L2. The second coil L2 and the capacitance circuit Cb constitute a parallel resonant circuit 25. The first coil L1 and the second coil L2 are electromagnetically coupled with each other.

In the antenna device 300a, the first antenna functions as a fed antenna fed by the feeder circuit 30, and the second antenna functions as a parasitic antenna not fed by the feeder circuit 30. The capacitance circuit Cb includes a plurality of capacitors Cb1 with different capacitances and a switch element Cb2 electrically connected to one of the plurality of capacitors Cb1. The capacitance of the capacitance circuit Cb can be varied by switching the capacitor Cb1 electrically connected by the switch element Cb2. The resonant frequency of the parallel resonant circuit 25 can be adjusted by varying the capacitance of the capacitance circuit Cb. The antenna device 300a can block a current flowing from the feeder circuit 30 to the second radiating element 12 over a wider bandwidth by adjusting the resonant frequency of the parallel resonant circuit 25, thereby widening the frequency bandwidth.

Furthermore, if a control circuit is provided to adjust the capacitance of the capacitance circuit Cb, the resonant frequency of the parallel resonant circuit 25 can be actively adjusted. For example, the antenna device 300a can adjust the capacitance of the capacitance circuit Cb by switching the capacitor Cb1 electrically connected by the switch element Cb2 over time using the control circuit, thereby adjusting the frequency band in which no current flows to the second radiating element 12.

The antenna devices 300 and 300a can be configured as described in Embodiment 1 and Embodiment 2.

### MODES

(1) An antenna device according to the present disclosure comprising:
a first radiating element to which a feeder circuit is connected;
a second radiating element;
a first coil connected to the first radiating element;
a second coil connected between the second radiating element and a ground electrode, and electromagnetically coupled to the first coil; and
a capacitance circuit connected in parallel with the second coil and constituting a parallel resonant circuit together with the second coil,
wherein a resonant frequency of the parallel resonant circuit is a frequency within a band of a fundamental resonance or a harmonic resonance of the first radiating element.
(2) The antenna device according to (1),
wherein the resonant frequency of the parallel resonant circuit is a frequency within a band of a third harmonic resonance of the first radiating element.
(3) The antenna device according to (1) or (2),
wherein a frequency of a fundamental resonance of the second radiating element is a frequency within a band of the fundamental resonance of the first radiating element.
(4) The antenna device according to any one of (1) to (3),
wherein conductors of the first coil and the second coil are wound such that a direction of magnetic flux generated by the first coil when current flows from the first radiating element toward the feeder circuit and a direction of magnetic flux generated by the second coil when current flows from the second radiating element toward the ground electrode are opposite to each other.
(5) The antenna device according to any one of (1) to (3),
wherein conductors of the first coil and the second coil are wound such that a direction of magnetic flux generated by the first coil when current flows from the first radiating element toward the feeder circuit is identical to a direction of magnetic flux generated by the second coil when current flows from the second radiating element toward the ground electrode.
(6) The antenna device according to any one of (1) to (5), further comprising:
a first matching network connected between the first coil and the feeder circuit.
(7) The antenna device according to any one of (1) to (6), further comprising:
a second matching network connected between the second coil and the ground electrode, and connected in series with the second coil and the capacitance circuit.
(8) The antenna device according to any one of (1) to (7),
wherein the capacitance circuit is a variable capacitance element.
(9) The antenna device according to any one of (1) to (7),
wherein the capacitance circuit includes
a plurality of capacitors with different capacitances, and
a switch element electrically connected to one of the plurality of capacitors.
(10) The antenna device according to any one of (1) to (9),
wherein the first coil is connected in series with the feeder circuit between the first radiating element and the ground electrode.
(11) The antenna device according to any one of (1) to (9),
wherein the first coil is connected in parallel with the feeder circuit between the first radiating element and the ground electrode.
(12) A communication terminal device according to the present disclosure comprising:
the antenna device according to any one of (1) to (11), and the feeder circuit that supplies current to the first radiating element.

The embodiments disclosed herein are illustrative in all respects and should not be considered as limiting. The scope of the present disclosure is defined by the claims, not by the description of the above embodiments, and it is intended that equivalents to the scope of the claims and all modifications within the scope of the claims be included within the scope of the present disclosure.

### REFERENCE SIGNS LIST

10 substrate, 11, 11a to 11e first radiating element, 12, 12a to 12e second radiating element, 20 transformer element, 30 feeder circuit, 100, 100a to 100e, 200, 300, 300a antenna device, 1000 communication terminal device.

1. An antenna device comprising:
a first radiating element to which a feeder circuit is connected;
a second radiating element;
a first coil connected to the first radiating element;
a second coil connected between the second radiating element and a ground electrode, and electromagnetically coupled to the first coil; and
a capacitance circuit connected in parallel with the second coil and constituting a parallel resonant circuit together with the second coil,
wherein a resonant frequency of the parallel resonant circuit is within a frequency band of a fundamental resonance or a harmonic resonance of the first radiating element.

2. The antenna device according to claim 1,
wherein the resonant frequency of the parallel resonant circuit is a frequency within a band of a third harmonic resonance of the first radiating element.

3. The antenna device according to claim 1,
wherein a frequency of a fundamental resonance of the second radiating element is a frequency within a band of the fundamental resonance of the first radiating element.

4. The antenna device according to claim 1,
wherein conductors of the first coil and the second coil are wound such that a direction of magnetic flux generated by the first coil when current flows from the first radiating element toward the feeder circuit and a direction of magnetic flux generated by the second coil when current flows from the second radiating element toward the ground electrode are opposite to each other.

5. The antenna device according to claim 1,
wherein conductors of the first coil and the second coil are wound such that a direction of magnetic flux generated by the first coil when current flows from the first radiating element toward the feeder circuit is identical to a direction of magnetic flux generated by the second coil when current flows from the second radiating element toward the ground electrode.

6. The antenna device according to claim 1, further comprising:
a first matching network connected between the first coil and the feeder circuit.

7. The antenna device according to claim 1, further comprising:
a second matching network connected between the second coil and the ground electrode and connected in series with the second coil and the capacitance circuit.

8. The antenna device according to claim 1,
wherein the capacitance circuit is a variable capacitance element.

9. The antenna device according to claim 8, further comprising a control circuit configured to vary a capacitance of the variable capacitance element over time to adjust a frequency band in which current flow from the feeder circuit to the second radiating element is suppressed.

10. The antenna device according to claim 1,
wherein the capacitance circuit includes
a plurality of capacitors with different capacitances, and
a switch configured to be selectively, electrically connected to one of the plurality of capacitors.

11. The antenna device according to claim 1,
wherein the first coil is connected in series with the feeder circuit between the first radiating element and the ground electrode.

12. The antenna device according to claim 1,
wherein the first coil is connected in parallel with the feeder circuit between the first radiating element and the ground electrode.

13. The antenna device according to claim 1,
wherein the first coil and the second coil are integrated in a single chip component forming a transformer element.

14. The antenna device according to claim 13, wherein the transformer element further comprises the capacitance circuit.

15. The antenna device according to claim 1, wherein the first radiating element constitutes a monopole antenna.

16. The antenna device according to claim 1, wherein the first radiating element constitutes an inverted-F antenna.

17. The antenna device according to claim 1, wherein the second radiating element constitutes a monopole antenna.

18. A communication terminal device comprising:
the antenna device according to claim 1, and
a feeder circuit configured to supply current to the first radiating element.

19. The communication terminal device according to claim 18, wherein the first radiating element, the second radiating element, and the first and second coils are mounted on a substrate, and the substrate is incorporated into a housing of the communication terminal device.

20. A method of operating an antenna device including a first radiating element, a second radiating element, a first coil connected to the first radiating element, a second coil connected between the second radiating element and a ground electrode and electromagnetically coupled to the first coil, and a capacitance circuit connected in parallel with the second coil, the method comprising:
supplying, by a feeder circuit, current to the first radiating element; and
blocking, by a parallel resonant circuit formed by the second coil and the capacitance circuit, current flow from the feeder circuit to the second radiating element at a resonant frequency of the parallel resonant circuit that falls within a frequency band of a fundamental resonance or a harmonic resonance of the first radiating element.
